(19) United States
(12) Patent Application Publication
(10) Pub. No.: US 2008/0206462 A1
(43) Pub. Date: Aug. 28, 2008

(54) BATCH DEPOSITION SYSTEM USING A SUPERCRITICAL DEPOSITION PROCESS

(75) Inventor: Hiroyuki ODE, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/035,467

(22) Filed: Feb. 22, 2008

(30) Foreign Application Priority Data
Feb. 22, 2007 (JP) 2007-042002

(51) Int. Cl. C23C 16/44

(52) U.S. Cl. 427/248.1; 118/719

(57) ABSTRACT

A batch deposition chamber for use in a supercritical deposition process is divided into a plurality of compartments each adapted to receive therein a wafer. A supercritical fluid is introduced into the compartments at the same flow rate via respective feed tubes for depositing a film on the wafers. Each of the ambient temperature and the surface temperature of the wafers is controlled at the same temperature among all the wafers by using temperature sensors provided for the respective wafers and a temperature controller.

This application is based upon and claims the benefit of priority from Japanese patent application No. 2007-042002, the disclosure of which is incorporated herein in its entirety by reference.

### BACKGROUND OF THE INVENTION

1. Field of the Invention

The present invention relates to a batch deposition system using a supercritical deposition process, and a method for depositing a film on a plurality of wafers by using the supercritical deposition process.

2. Description of the Related Art

In recent years, semiconductor devices have been remarkably improved in the operating speed thereof and developed to have smaller dimensions. Therefore, it is apprehended that the conventional filming processes, such as chemical vapor deposition (CVD) process and plasma-enhanced vapor deposition (PVD) process, may fail to provide thin films that can meet the demand in the near future with respect to, for example, quality, electric characteristic and step coverage. In view of this fact, it is demanded that new thin-film deposition processes be developed as soon as possible. To meet such a demand, new deposition techniques have been developing. Among those new developing techniques, there are atomic layer deposition (ALD) process and supercritical deposition process. In the supercritical deposition process, the ambient medium for the wafer is maintained in a supercritical state. In this state, the supercritical deposition process considerably differs from the conventional deposition process that uses a vacuum as the ambient medium for the wafer. The “supercritical state” is such that a substance used for the ambient medium assumes both the nature of a gas state and the nature of a liquid state at a temperature and a pressure exceeding the critical point of the substance.

In the supercritical deposition process, the medium (e.g., supercritical CO₂) has a solvent power or function similarly to a liquid solvent. The medium can therefore dissolve the precursor, no matter how high the vapor pressure is, and thus the precursor can be introduced into the deposition chamber as it is. Hence, the precursor can be a solid one, a liquid one or a gaseous one. On the other hand, if the medium used for dissolving the precursor is a gas, the precursor can be transported at a high speed and can be introduced into microstructures of the semiconductor wafer by the function of itself, thereby achieving a higher step coverage on the wafer. Moreover, any supercritical fluid can serve to provide a film having a lower impurity concentration, because it has a cleaning property as proved by the fact that it is applied as a washing medium.

The supercritical deposition process exhibits a high potential of use, as is reported through the basic researches conducted all over the world. Nevertheless, practical processes and practical systems have yet to be developed in the future. In particular, the technical knowledge helpful to the development of systems that can perform the supercritical deposition process is next to non-existent, because the supercritical state is a high-pressure state that has never been used in semiconductor manufacturing systems. Inevitably, it is difficult to develop a supercritical deposition system that can achieve a higher throughput and a higher product yield.

In recent years, a variety of deposition systems of a single-wafer processing type or in-line processing type have been developed one after another, each of which is designed to perform a supercritical deposition process. In any system of the single-wafer processing type, the high-pressure deposition chamber can have smaller dimensions. It is therefore relatively easy to control the temperature and flow of the substance in the high-pressure deposition chamber. A thin-film deposition system of a single-wafer processing type is described in, for example, JP-A-2006-169601. A thin-film deposition system of the single-wafer processing type is, however, less desirable than a thin-film deposition system of a batch processing type. This is because a system of the batch-processing type using a high-pressure chamber can provide a film on a larger number of wafers at a time, thereby achieving a higher throughput for the deposition.

However, the deposition temperature is difficult to control in a large-dimension, high-pressure chamber that can receive therein a large number of wafers at the same time. That is, the temperature distribution in the large-dimension, high-pressure chamber is not uniform in general. More precisely, the temperature is higher in the upper portion of the chamber and is lower in the lower portion of the chamber. Inevitably, it is extremely difficult to deposit a film having a uniform quality among a large number of wafers in the large-dimension, high-pressure chamber used for the supercritical deposition process. Further, a high-pressure chamber having larger dimensions is more difficult to achieve therein a uniform control of the complicated flow of the supercritical fluid.

It is assumed here, as illustrated in FIG. 7, that a plurality of wafers 14 are arranged in a high-pressure chamber 11, one above another, each being held horizontally. Even if the high-pressure chamber 11 may be uniformly heated from outside, the ambient temperature, i.e., the temperature of the supercritical fluid, in the upper portion of the high-pressure chamber 11 is considerably different from the ambient temperature in the lower portion of the high-pressure chamber 11. Further, convection of the fluid develops in the chamber, inevitably because of the vertical temperature gradient existing in the chamber. As a result, a reagent is difficult to provide in a uniform rate to the wafers 14.

In addition, the temperature gradient results in a density gradient in the supercritical fluid. The density gradient in turn results in a density gradient of the precursor reagent. It should be noted here that the density of the supercritical fluid is proportional to the solubility that the precursor reagent exhibits in the supercritical fluid. Hence, the respective films formed on the wafers 14 held in the high-pressure chamber significantly differ in the quality thereof from one another, depending on the position of the wafers in the vertical direction. This is inevitable because of the temperature gradient, convection and density gradient of the precursor, as described above.

### SUMMARY OF THE INVENTION

It is an object of the present invention to improve the conventional supercritical batch deposition system that uses the supercritical reagent to form a film on a plurality of wafers at the same time, which system is capable of depositing the film to have a uniform thickness among the plurality of semiconductor wafers.

The present invention provides a supercritical batch deposition system including: a pressure chamber that includes at least one partition for dividing the pressure chamber into a plurality of compartments in a vertical direction, each of the compartments being adapted to receive therein a wafer; a plurality of reagent inlet ports that introduce supercritical reagent into the respective compartments; a plurality of temperature sensors each for measuring a temperature in a corresponding one of the compartments; and a temperature controller that controls the temperature of the compartments at a target temperature based on the temperature measured by the temperature sensors.

The present invention also provides a method for depositing a film by using a supercritical batch deposition process including: receiving each of a plurality of wafers in a corresponding one of a plurality of compartments formed in a pressure chamber; introducing a supercritical reagent into the compartments; controlling a temperature of the compartments at a target temperature; and controlling a flow rate of the reagent introduced into the compartments at a target flow rate.

The above and other objects, features and advantages of the present invention will be more apparent from the following description, referring to the accompanying drawings.

### BRIEF DESCRIPTION OF THE DRAWINGS

FIG. 1 is a sectional view of a high-pressure chamber of a supercritical batch deposition system according to an embodiment of the present invention;

FIG. 2A is a partial sectional view showing the detail of the high-pressure chamber illustrated in FIG. 1;

FIG. 2B is a bottom view of one of the wafers arranged in the high-pressure chamber;

FIG. 3 is a block diagram showing the supercritical batch deposition system of the embodiment;

FIG. 4 is a block diagram of a supercritical-solution adjusting system that feeds a filming precursor;

FIG. 5 is a block diagram of a supercritical-solution adjusting system that feeds hydrogen;

FIG. 6 is a block diagram of a supercritical-solution adjusting system that uses a solid reagent as a filming precursor; and

FIG. 7 is a sectional view of a high-pressure chamber of a comparative example of the supercritical batch deposition system.

### DETAILED DESCRIPTION OF THE INVENTION

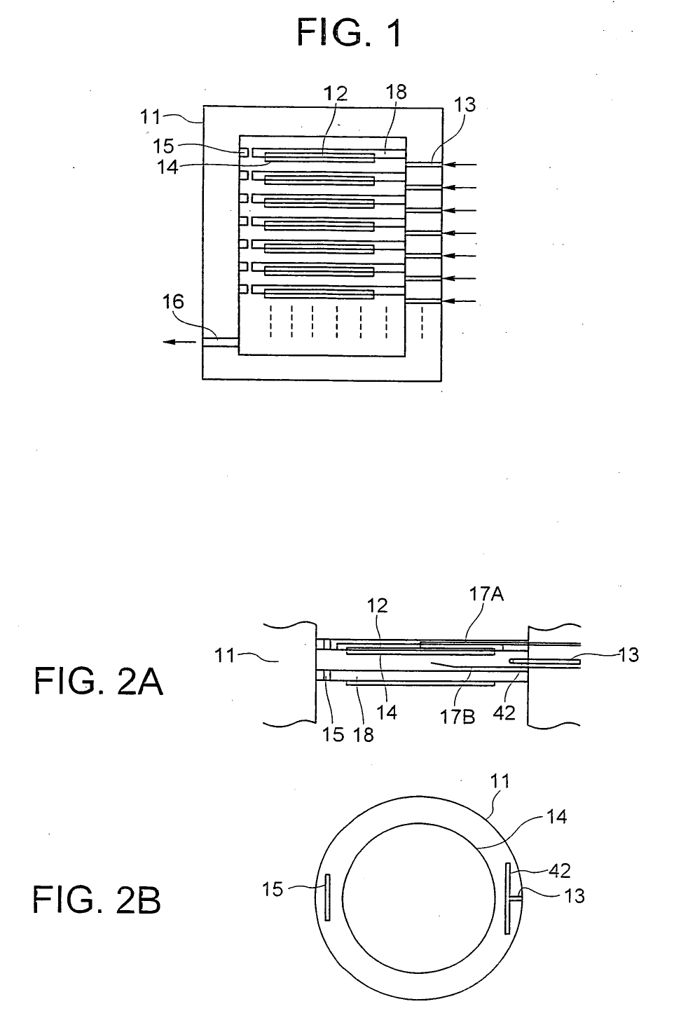

An exemplary embodiment of the present invention will be described with reference to the accompanying drawings. FIG. 1 is a sectional view of a high-pressure chamber of a supercritical batch deposition system according to an embodiment of the present invention. FIG. 2A is a partial sectional view showing the detail of the high-pressure chamber illustrated in FIG. 1. FIG. 2B is a bottom view showing one of the wafers received in the batch deposition system. The deposition system of the present embodiment is of a batch processing type that uses a supercritical fluid as the process medium. The supercritical batch deposition system includes the high-pressure chamber shown in FIG. 1, and a supercritical-solution adjusting system and a temperature control system, both of which will be described later in detail.

The high-pressure chamber 11 includes a plurality of compartments arranged one above another. The compartments are formed by dividing the interior of the deposition chamber with a plurality of horizontal partitions 18. Each of the wafers 14 is received in one of the compartments. The chamber 11 further includes a plurality of heaters 12, a plurality of reagent inlet ports 13, and a plurality of through-holes 15, a supercritical-fluid outlet port 16, a plurality of thermocouples 17A, and a plurality of thermocouples 17B.

The heaters 12 are provided to heat the respective wafers 14. The reagent inlet port 13 includes a nozzle 42 at the distal end thereof. The through-holes 15 are formed in the respective partitions to allow a corresponding compartment to communicate with the adjacent compartment. The supercritical-fluid outlet port 16 is provided at one side of the chamber 11 opposing the side at which the reagent inlet ports 13 are provided, to allow the used reagent to be discharged from the high-pressure chamber 11. The thermocouples 17A measure the surface temperature of the respective wafers 14. The thermocouples 17B measure the ambient temperature of the respective wafers 14 in the compartments. The wafers 14 are laid on the surface of the floor or attached onto the ceiling of the compartments, and the heaters 12 are embedded in the floor or ceiling of the compartments in order to heat the wafers 14. The heaters 12 may have thereon an adiabatic layer in order to prevent heat dissipation. Alternatively, or in addition thereto, the wall of the compartments may be made of adiabatic material for the same purpose.

The supercritical-solution adjusting system, which feeds the reagent into the high-pressure chamber 11, adjusts the feed rate of a filming precursor solution or reaction reagent solution, which is a supercritical fluid. The supercritical-solution adjusting system also controls the filming precursor solution to be introduced into all the compartments of the high-pressure chamber 11 at a uniform rate among the compartments. On the other hand, the temperature control system adjusts the surface temperature of the wafers 14 and the ambient temperature of the wafers 14 in the compartments so that all the wafers 14 have a similar filming temperature and the all compartments have a similar internal temperature.

The reagent inlet ports 13, each of which is provided in a corresponding one of the compartments and having a nozzle 42 at the distal end thereof, are communicated via respective feed tubes with the supercritical-solution adjusting system. In the supercritical-solution adjusting system, the filming precursor solution or reaction reagent solution is fed by a reagent-dissolving system, e.g. a reagent-dissolving chamber or a reagent dissolving loop while using flow rate controllers provided in the respective feed tubes. The flow rate controllers control the supercritical solution flowing in the feed tubes so that the solution is introduced into the compartments at the same flow rate.

The temperature control system adjusts the surface temperature of the wafers 14 and the ambient temperature in the compartments. More specifically, the surface temperature of the wafers 14 is controlled by the heaters 12 and the thermocouples 17A provided on the wafers 14 or in the vicinity of the wafers 14, whereby all the wafers 14 received in the high-pressure chamber 11 have the same surface temperature or filming temperature. A single or a plurality of thermocouples may be provided for each of the wafers 14. The ambient temperature of the wafers 14 in the compartments is controlled using at least one thermocouple for measuring the ambient temperature of each wafer 14 and a heat exchanger provided in each feed tube, whereby all the compartments provide the same ambient temperature for the wafers 14.

As described above, the wafers 14 are received in the respective compartments and controlled independently of one another, in terms of the wafer ambient such as temperature of the wafers, and feed density and flow rate of the supercritical reagent. Thus, a desired film can be formed at the same deposition rate on all the wafers received in the high-pressure chamber. The resultant film will have similar thickness and film property on all the wafers.

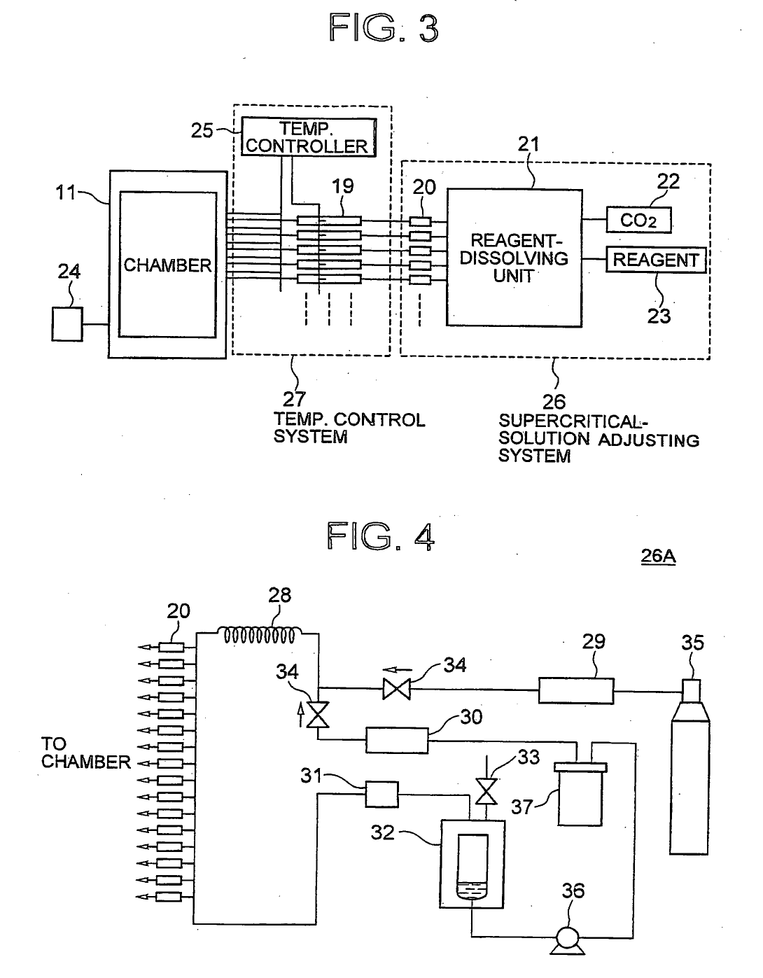

FIG. 3 shows a supercritical batch deposition system, which is a concrete example of the present embodiment. The high-pressure chamber 11 is such that described with reference to FIG. 1 and FIGS. 2A and 2B. The high-pressure chamber 11 may receive therein 25 wafers, for example, at a time. The wafers are fixed onto the ceiling of the compartments. The deposition system includes first and second feed systems each including a supercritical-solution dissolving system 26 and a temperature control system 27, although FIG. 3 shows only one of the first and second feed systems. The first feed system is used for supplying the filming precursor reagent, whereas the second feed system is used for supplying hydrogen. The first and second feed systems each include 25 feed tubes connected to 25 compartments provided in the high-pressure deposition chamber 11.

The supercritical-solution dissolving system 26 in each of the first and second feed systems includes a reagent dissolving unit 21, a carbon-dioxide feed unit 22 and a reagent feed unit 23. Reagent and carbon dioxide are fed to the reagent-dissolving unit 21 from the reagent feed unit 23 and the carbon-dioxide feed unit 22. The reagent fed from the reagent feed unit 23 is dissolved in the reagent-dissolving unit 21. The reagent thus dissolved is supplied to the compartments of the high-pressure chamber 11 via flow rate controllers 20 and heat exchangers 19.

The internal pressure of the chamber 11 is controlled by a back-pressure adjuster 24. The heat that each heat exchanger 19 applied to the reagent is controlled by a temperature controller 25 independently of the heat that any other heat exchanger 19 applies to the reagent.

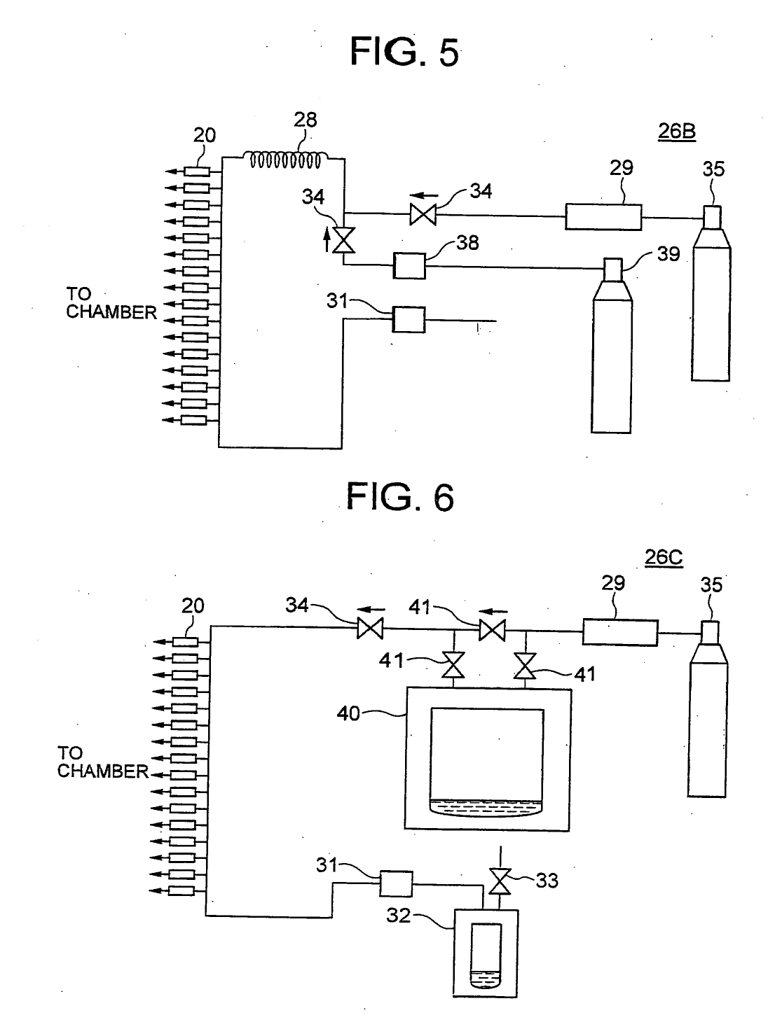

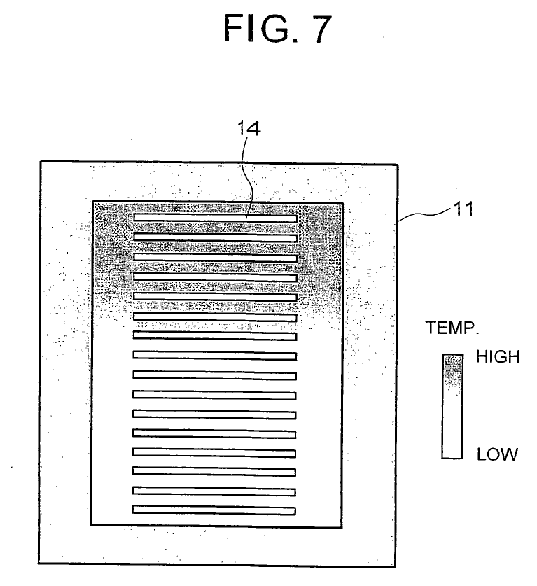

FIG. 4 shows a supercritical-solution adjusting system of the first feed system that feeds a filming reagent precursor. FIG. 5 shows a supercritical-solution adjusting system of the second feed system that feeds hydrogen. It should be noted that a common temperature controller 25 may be used for the supercritical-solution adjusting systems of the first and second feed systems that feed the filming precursor and hydrogen.

The supercritical-solution adjusting system 26A shown in FIG. 4 includes a carbon-dioxide feed unit, a reagent feed unit, a reagent-mixing loop 28 for mixing the reagent with carbon dioxide, feed rate controllers 20, and a reagent recovery unit. The carbon-dioxide feed unit includes a carbon-dioxide cylinder 35, a high-pressure pump 29 for supplying carbon dioxide from the carbon-dioxide cylinder 35, and a check valve 34. The reagent feed unit includes a reagent barrel 37 receiving therein reagent to be used as the precursor, a high-pressure reagent pump 30 for feeding the precursor reagent, and a check valve 34. The reagent recovery unit includes a back-pressure adjuster 31, a chamber 32 for recovering the precursor reagent, a relief valve 33, and a reagent recovery pump 36 for circulating the unused reagent to the reagent barrel 37 for recovery.

As shown in FIG. 5, the supercritical-solution adjusting system 26B of the second feed system that feeds hydrogen includes a carbon-dioxide feed unit, a hydrogen feed unit, a reagent-mixing loop 28, feed rate controllers 20, and a recovery unit. The carbon-dioxide feed unit includes a carbon-dioxide cylinder 35, a high-pressure pump 29 for feeding carbon dioxide toward the high-pressure deposition chamber via the temperature control system, a check valve 34, and a plurality of flow rate controllers 20. The hydrogen feed unit includes a hydrogen cylinder 39, a high-pressure mass-flow controller 38 for feeding hydrogen from the hydrogen cylinder 39 toward the high-pressure chamber, a check valve 34. The recovery unit includes a back-pressure adjuster 31 coupled to the reagent-mixing loop 28 mixing hydrogen with carbon dioxide.

FIG. 6 shows a supercritical-solution adjusting system that feeds a solid reagent as a filming precursor. The supercritical-solution adjusting system 26C includes a carbon-dioxide feed unit, a reagent dissolving chamber 40, feed rate controllers 20, and a reagent recovery unit. The carbon-dioxide feed unit includes a carbon-dioxide cylinder 35, a high-pressure pump 29 for feeding carbon dioxide to the reagent dissolving chamber 40, and a bypass valve 41. The reagent dissolving chamber 40 are associated with a pair of high-pressure valves 41. The reagent recovery unit includes a back-pressure adjuster 31, a precursor recovery chamber 32 and a relief valve 33. The reagent-dissolving chamber 40 receives therein the solid reagent in advance and dissolves the solid reagent into carbon dioxide fed from the carbon-dioxide feed system, and feeds the dissolved reagent toward the high-pressure chamber. The reagent recovery unit recovers the excessive dissolved reagent.

The solid reagent is, for example, copper hexafluoroacetylacetone (Cu(hfa)). After thoroughly dissolving the reagent in the reagent-dissolving chamber 30, the reagent is introduced into the compartments of the high-pressure chamber 11 via the temperature control system 27. In the reagent-dissolving chamber 30, the solid reagent is stirred by a magnetic stirrer or a stirring propeller, and thereby dissolved into the carbon dioxide at a higher efficiency.

In accordance with the type of the reagent to be used for deposition, any one of the three supercritical-solution adjusting systems 26A, 26B and 26C shown in FIGS. 4, 5 and 6, respectively, may be used, or any possible combination of two or three of the above supercritical-solution adjusting systems may be used. Further, if a larger number of reagents are to be used for filming reaction, a larger number of reagent inlet ports 13 may be provided for each of the compartments, and a corresponding number of nozzles 32 may be provided at the distal end.

Operation of the batch deposition system of the present embodiment as described above will be described hereinafter. First, twenty-five wafers 14 are inserted in the high-pressure chamber 11. Then, pure supercritical carbon dioxide is introduced into the high-pressure chamber 11, by using the tube of the feed system configured to supply the filming precursor reagent or the tube of the feed system configured to supply hydrogen, or the tubes of both the feed systems. At this stage, neither a precursor nor hydrogen is introduced into the high-pressure chamber 11. The internal pressure of the chamber 11 is, for example, 13 MPa. The internal pressure is adjusted to this target value by using the back-pressure adjuster 24, which is provided at the outlet port for the supercritical fluid.

After the pressure in the chamber 11 reaches the target value, the heaters 12 are turned on to heat the wafers 14 up to a target filming temperature (e.g., 250° C.), while feeding supercritical carbon dioxide at a preset flow rate. At this stage, all the wafers 14 in the high-pressure chamber 11 are controlled to achieve the target fixed temperature for the wafers 14. In addition, the heat exchangers 19 and the thermocouples 17B for measuring the ambient temperatures are used to control and maintain the ambient temperature of the wafers 14 in the respective compartments at a target temperature lower than the filming temperature, for example, at 100° C. or below.

After all the compartments have been set in a condition such that a filming reaction efficiently develops, the filming precursor and hydrogen are introduced into the compartments. More precisely, the reagent pump 30 for feeding the precursor reagent feeds the precursor reagent (e.g., copper hexafluoro-acetyleacetonato vinyltrimethylsilane, Cu(hfa)(VTMS)), from the reagent barrel 37 toward the high-pressure chamber 11. The precursor reagent is substantially thoroughly mixed with the supercritical carbon dioxide at a given mixing ratio in the reagent-mixing loop 28. The resultant mixture is distributed to the feed tubes communicated with the respective compartments. The flow rate controllers 20 control the flow rate of the carbon dioxide thus distributed, whereby the carbon dioxide is fed to all the compartments at the same or similar flow rate among the compartments.

In the present embodiment, the high-pressure mass-flow controller 38 is used to feed hydrogen. After the hydrogen is mixed with carbon dioxide at a given mixing ratio, the resulting mixture is introduced into the compartments at the same feed rate. The filming precursor and the hydrogen are introduced into the compartments, either simultaneously or alternately, through the reagent inlet ports 13 and nozzles 32 provided for the high-pressure chamber 11. After the precursor and the hydrogen are introduced into the compartments in order to obtain a target thickness for a Cu film, for example, pure supercritical carbon oxide is fed to the compartments, thereby performing complete purging in the high-pressure chamber 11. Finally, the heating by means of the heaters 12 is stopped, and the pressure in the high-pressure chamber 11 is lowered. The Cu film formed on the plurality of wafers 14 by performing the process described above exhibited electric resistivity as low as pure Cu does.

The deposition system of the present embodiment as described above provided, on wafers of the same batch, a film having a uniform quality among the wafers. Since the deposition system of the present embodiment is of a batch-processing type, the present embodiment achieves a high filming rate, which is inherent to the supercritical deposition process.

In the supercritical deposition system of the batch-processing type according to the above embodiment, the resultant film formed on the wafers has a uniform thickness due to the uniform deposition rate among the wafers. In addition, the batch processing achieves a higher throughput for deposition of the film on the wafers.

The present invention is appropriately applied in particular to processes of forming a variety of films in the manufacture of semiconductor devices. Electrically conductive films, semiconductor films and insulating films (dielectric films) can be exemplified as the films formed by using the system and the process of the present invention.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A supercritical batch deposition system comprising:
a pressure chamber that includes at least one partition for dividing said pressure chamber into a plurality of compartments in a vertical direction, each of said compartments being adapted to receive therein a wafer;
a plurality of reagent inlet ports that introduce supercritical reagent into respective said compartments;
a plurality of temperature sensors each for measuring a temperature in a corresponding one of said compartments; and
a temperature controller that controls the temperature of said compartments at a target temperature based on the temperature measured by said temperature sensors.

2. The batch deposition system according to claim 1, wherein said plurality of temperature sensors include at least two temperature sensors for each of said compartments, one and the other of said two temperature sensors measuring an ambient temperature and a surface temperature, respectively, of each of said wafers.

3. The batch deposition system according to claim 2, wherein said temperature controller controls the surface temperature of said wafers at a fixed temperature based on the surface temperature measured by said one of said two temperature sensors, and controls the ambient temperature of said wafers at another fixed temperature based on the ambient temperature measured by the other of said two temperature sensors.

4. The batch deposition system according to claim 1, wherein said pressure chamber comprises therein a plurality of supercritical-solution inlet ports that introduce a solution prepared by dissolving the reagent in a supercritical fluid into respective said compartments.

5. The batch deposition system according to claim 4, wherein said reagent is introduced into said plurality of compartments at the same flow rate.

6. The batch deposition system according to claim 1, further comprising a plurality of flow rate controllers each in association with a corresponding one of said target inlet ports.

7. The batch deposition system according to claim 6, wherein said partition has therein a through-hole that communicates together adjacent two of said compartments.

8. A method for depositing a film by using a supercritical batch deposition process comprising:
receiving each of a plurality of wafers in a corresponding one of a plurality of compartments formed in a pressure chamber;
introducing a supercritical reagent into said compartments;
controlling a temperature of said compartments at a target temperature; and
controlling a flow rate of said reagent introduced into said compartments at a target flow rate.
